(19) United States
(12) Patent Application Publication
(10) Pub. No.: US 2010/0328753 A1
(43) Pub. Date: Dec. 30, 2010

(54) Optical module, integrated semiconductor optical device and manufacturing method thereof

(75) Inventors: Hiroaki Hayashi, Kokubunji (JP); Shigeki Makino, Kokubunji (JP); Takeshi Kitatani, Hino (JP); Shigehisa Tanaka, Koganei (JP)

Correspondence Address: Juan Carlos A. Marquez;c/o Stites & Harbison PLLC, 1199 North Fairfax Street, Suite 900, Alexandria, VA, 22314-1437, US

(73) Assignee: Opnext Japan, Inc.

(21) Appl. No.: 12/801,773

(22) Filed: Jun. 24, 2010

(30) Foreign Application Priority Data
Jun. 26, 2009 (JP) JP2009-151918
Apr. 19, 2010 (JP) JP2010-095616

(51) Int. Cl. G02F 1/015; H01L 21/18; H01S 3/00

(52) U.S. Cl. 359/279; 438/39; 257/E21.085; 359/333

(57) ABSTRACT

An integrated semiconductor optical device and an optical module capable of the high-speed and large-capacity optical transmission are provided. In an integrated semiconductor optical device in which a plurality of optical devices buried with semi-insulating semiconductor materials are integrated on the same semiconductor substrate and an optical module using the integrated semiconductor optical device, configurations (material and electrical characteristics) of the buried layers are made different for each of the optical devices.

### CROSS-REFERENCE TO RELATED APPLICATION

The present application claims priority from Japanese Patent Application No. 2009-151918 filed on Jun. 26, 2009 and Japanese Patent Application No. 2010-095616 filed on Apr. 19, 2010, the contents of which are hereby incorporated by reference to these applications.

### TECHNICAL FIELD OF THE INVENTION

The present invention relates to an integrated semiconductor optical device for optical communication and an optical module in which the optical device is mounted. More particularly, it relates to an integrated semiconductor optical device in which plural types of semiconductor optical devices including an optical modulator are monolithically fabricated on the same semiconductor substrate and an optical module using the integrated semiconductor optical device.

### BACKGROUND OF THE INVENTION

With the widespread availability of the broadband service that has been increasing the internet contents and the internet population year after year, further increase in communication speed and communication capacity has been required in the information communications service.

However, for sufficiently satisfying these demands, a higher-speed and higher-output-power light source has to be incorporated in an optical communication device. As a low-cost high-output-power light source with low power consumption, there is a light source in which a semiconductor optical modulator and a semiconductor laser device are monolithically integrated on the same semiconductor substrate. In this type of integrated semiconductor optical device, a semiconductor laser device, an optical modulator, an optical amplifier and other optical devices to be a light source are fabricated on the same semiconductor substrate, and therefore, a high-output-power and easily-mountable compact optical device with low loss can be realized by the high optical coupling by the semiconductor process.

Incidentally, as the typical basic structure of the semiconductor laser device for optical communication, there are roughly two types of structures such as the ridge waveguide (RWG) structure and the buried-hetero (BH) structure (hereinafter, simply referred to as buried structure). It has been known that, since the efficient confinement of carriers and light are necessary in the high-output-power semiconductor laser device, the buried structure in which a semi-insulating semiconductor layer is used as a current block layer is more advantageous than the ridge waveguide structure. This is because, since the carrier leakage is suppressed by a buried layer made of a semi-insulating semiconductor material buried in a sidewall of mesa stripe in the buried structure, the current can be efficiently Injected only into an active layer.

The conventional typical buried-type semiconductor laser device as described above uses a semi-insulating semiconductor crystal doped with iron (Fe) as a material of the semi-insulating semiconductor layer.

However, since Fe interdiffuses by its nature with zinc (Zn) generally used as a p-type dopant, the problem that Zn doped in a p-type clad layer and a p-type contact layer of the laser device is diffused into the semi-insulating semiconductor layer to reduce the insulation and Fe is reversely diffused from the buried layer to the clad layer and the contact layer to reduce the conductivity has been pointed out. Furthermore, the problem that the carriers overflow due to the shift of the carrier energy to a high-energy side in the high-temperature operation and the device characteristics are significantly deteriorated and the problem that Zn ejected to an interstitial site by the interdiffusion is diffused also into the active layer of the laser device to reduce the light-emission efficiency of the active layer have also been pointed out.

A recent report has stated that, when a semi-insulating semiconductor crystal doped with ruthenium (Ru) is used, the interdiffusion with Zn is suppressed compared with a semi-insulating semiconductor crystal doped with Fe (A. Dadger et al., Applied Physics Letters Vol. 73, No. 26, pp. 3878-3880 (1998) (Non-Patent Document 1)).

Since the carriers can be efficiently confined in the active layer when the semi-insulating semiconductor crystal doped with, Ru is used for the buried layer, the probability of increasing the light output of the semiconductor laser was increased. Also in the conventional typical EA optical modulator, the semi-insulating semiconductor crystal doped with Ru is used for the buried layer. In this case, since the effective thickness of an undoped layer can be increased by the suppression of the Zn diffusion, it leads to the reduction in parasitic capacitance, and the fabrication of a broadband device is expected. Specifically, Japanese Patent No. 4049562 (Patent Document 2) discloses an EA optical modulator in which a thin buried layer made of a semi-insulating semiconductor material doped with Ru is provided between a semi-insulating semiconductor layer doped with Fe and a mesa stripe, thereby preventing the diffusion of Fe from the buried layer made of the semi-insulating semiconductor material doped with Fe to the mesa stripe. Also, it has been known that, when the optical modulator is driven at high speed and with high output power, photocarriers generated in the active region are retained and piled up within the active region (M. Suzuki et al., Electronics Letters Vol. 25, No. 2 pp. 88-89 (1989) (Non-Patent Document 2)).

### SUMMARY OF THE INVENTION

The inventors of the present invention actually studied the characteristics of the electro-absorption (EA) optical modulator adopting the buried structure. According to the result of the study, in the case of the EA optical modulator, the pile up of photocarriers is likely to occur due to the operation principle that it quenches by the light absorption, and when the pile up of the photocarriers occurs, the internal electric field is generated due to the gradient of carriers accumulated in a quantum well (QW) layer of the EA optical modulator, and the screening in which the external electric field is alleviated, the free carrier absorption which is the light absorption by piled-up free carriers and the intervalence band absorption (IVBA) which is the light absorption by piled-up holes are caused, and therefore, it can be understood that the characteristics are not suitable for the operation of the high-speed and high-output-power EA optical modulator. Furthermore, in the higher speed, that is, as the sweep rate of the electric field in the quantum well layer becomes higher, the pile up is more likely to occur, and more photocarriers are generated and the influence of the pile up is thus increased as the EA optical modulator is driven at higher output power. There results revealed that the suppression of the pile up is indispensable for fabricating the high-speed and high-output-power EA optical modulator and the integrated semiconductor optical device including the EA optical modulator that are required in the optical communication system. Further, the minute light absorption occurs also in the Mach Zehnder (MZ) optical modulator and the semiconductor optical phase modulator that induce the change in refractive index, and this causes the chirping. Therefore, it can be said that the discharge of the photocarriers generated by the light absorption is the issue to be achieved not only in the above-described EA optical modulator but also in the various types of semiconductor optical modulators and the entire integrated semiconductor optical devices including them.

In Japanese Patent Application Laid-Open Publication No. 8-162664 (Patent Document 1), in order to prevent the pile up of the photocarriers of the semiconductor light-receiving device, the photocarriers are swept to the clad layer by appropriately reducing the barrier to the clad layer, but when it is applied to the optical modulator, a new problem of the degradation in the extinction ratio caused by the reduction of the barrier occurs.

Also, although the increase in resistance of a gain region buried layer (buried layer of the semiconductor laser region and the optical amplifier region) is necessary for obtaining the higher output of the semiconductor laser and the optical amplifier, nothing is considered for the change of the resistivity of an optical modulation region buried layer.

More specifically, in the burying method using the same material as the gain region buried layer to the optical modulation region, the problem of the pile up that once has been improved in the Patent Document 1 is probably worsened due to the optical modulation region buried layer made of the material with the same resistance as that of the gain region buried layer.

Also, in the technology described in the Patent Document 2, the fabrication of the high-output-power semiconductor laser device and the optical modulator with the low parasitic capacitance can be certainly expected by disposing a thin Ru-doped semi-insulating semiconductor layer between the Fe-doped semi-insulating semiconductor layer and the mesa stripe. However, this technology cannot expect any improvement for the pile up of the photocarriers of the high-speed and high-output-power optical modulator, and since the Ru-doped semi-insulating semiconductor layer is more likely to have high resistance than the Fe-doped semi-insulating semiconductor layer, the problem due to the pile up is rather worsened than improved. As described above, for the entire integrated semiconductor optical device in which the semiconductor laser or the optical amplifier and the optical modulator are integrated, the buried structure that can achieve both the increase in the light output of the semiconductor laser and the optical amplifier and the solution of the problem of the pile up in the optical modulator has not been proposed.

An object of the present invention is to realize an integrated semiconductor optical device that can achieve both the increase in the light output of the semiconductor laser and the optical amplifier and the high-speed optical modulation of the optical modulator and also realize the long-distance and large-capacity transmission by applying the integrated semiconductor optical device to an optical module.

For the achievement of the above-described object, in the present invention, instead of adopting the structure of the conventional concept in which the mesa stripe in a gain region such as a semiconductor laser device and an optical amplifier and the mesa stripe in the optical modulation region are buried with the same semi-insulating semiconductor material with the equivalent resistivity, the structure of the new concept in which the buried layer of each optical device is individually set in order to control the carrier leakage to the buried layer for each of the integrated optical devices is adopted. Specifically, the resistance of the buried layer is adjusted in accordance with the characteristics of the optical devices for each of the regions that make up the individual optical devices (for example, gain region (semiconductor laser, optical amplifier) and optical modulation region (EA optical modulator)) so that each of the optical devices can have the optimum characteristics. In a particularly preferred embodiment, as a material of the gain region buried layer that buries the mesa stripe (in particular, active layer) in the gain region that makes up the semiconductor laser device and the optical amplifier, a semi-insulating semiconductor material with high resistance is used, and as a material of the optical modulation region buried layer that buries the mesa stripe (in particular, active region) in the optical modulation region that makes up the EA optical modulator, a semi-insulating semiconductor material with lower resistance compared with that of the gain region buried layer is used.

Furthermore, for the adjustment of the resistivity of the buried layers, preferably, an Ru-doped semi-insulating semiconductor material with less interdiffusion with Zn is used as the gain region buried layer so as to achieve the high output power, and an Fe-doped semi-insulating semiconductor material is used as the optical modulation region buried layer so as to appropriately distill the photocarriers to the buried layer without the excessive pile up of the photocarriers in the active region of the optical modulator. According to this embodiment, the carriers can be efficiently swept from the active region without reducing the barrier in the stacking direction to which the electric field is applied, and the screening and the inter-valence band absorption (IVBA) due to the piled-up holes can be suppressed. In addition, since the Fe diffused from the buried layer into the active region promotes the re-coupling of the generated photocarriers, the occurrence of the pile up can be suppressed also in this respect.

Note that, since the optical signals are not taken out in the integrated semiconductor optical device according to the present invention unlike the semiconductor light-receiving device of the Patent Document 1, the promotion of the non-radiative transition by the impurity doping is effective.

Furthermore, if the resistance of the optical modulation region buried layer adjusted to be lower than the resistance of the gain region buried layer is excessively reduced, the current is induced by the bias and more power is wasted, so that the efficient operation of the optical device is inhibited. Therefore, the resistivity is preferably set to a predetermined range, that is, within the range of 10⁴ to 10⁷ Ω·cm.

According to the present invention, the integrated semiconductor optical device capable of achieving the long-distance and large-capacity transmission and the optical module using the integrated semiconductor optical device can be provided.

### BRIEF DESCRIPTIONS OF THE DRAWINGS

FIG. 1 is a cutaway perspective view showing the principal part of the integrated semiconductor optical device according to the first embodiment of the present invention;

FIG. 2 is a graph showing the comparison in the rising time of the waveform of the integrated semiconductor optical devices of the first embodiment of the present invention and the comparative examples 1 and 2;

FIG. 3 is a table showing the comparison in the operation at 55° C. of the integrated semiconductor optical devices of the first embodiment of the present invention and the comparative examples 3 and 4;

FIG. 4 is a cutaway perspective view showing the principal part of the integrated semiconductor optical device according to the fourth embodiment of the present invention;

FIG. 5 is a cutaway perspective view showing the principal part of the integrated semiconductor optical device according to the second embodiment of the present invention;

FIG. 6 is a perspective view showing an example of the manufacturing method of the integrated semiconductor optical device of the present invention;

FIG. 7 is a perspective view showing an example of the manufacturing method of the integrated semiconductor optical device of the present invention;

FIG. 8 is a perspective view showing an example of the manufacturing method of the integrated semiconductor optical device of the present invention;

FIG. 9 is a perspective view showing an example of the manufacturing method of the integrated semiconductor optical device of the present invention; and

FIG. 10 is a configuration diagram showing a transceiver (embodiment of the optical module) using the integrated semiconductor optical device according to one of the first to fourth embodiments.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof will be omitted. In addition, the description of the same or similar portions is not repeated in principle unless particularly required in the following embodiments.

### First Embodiment

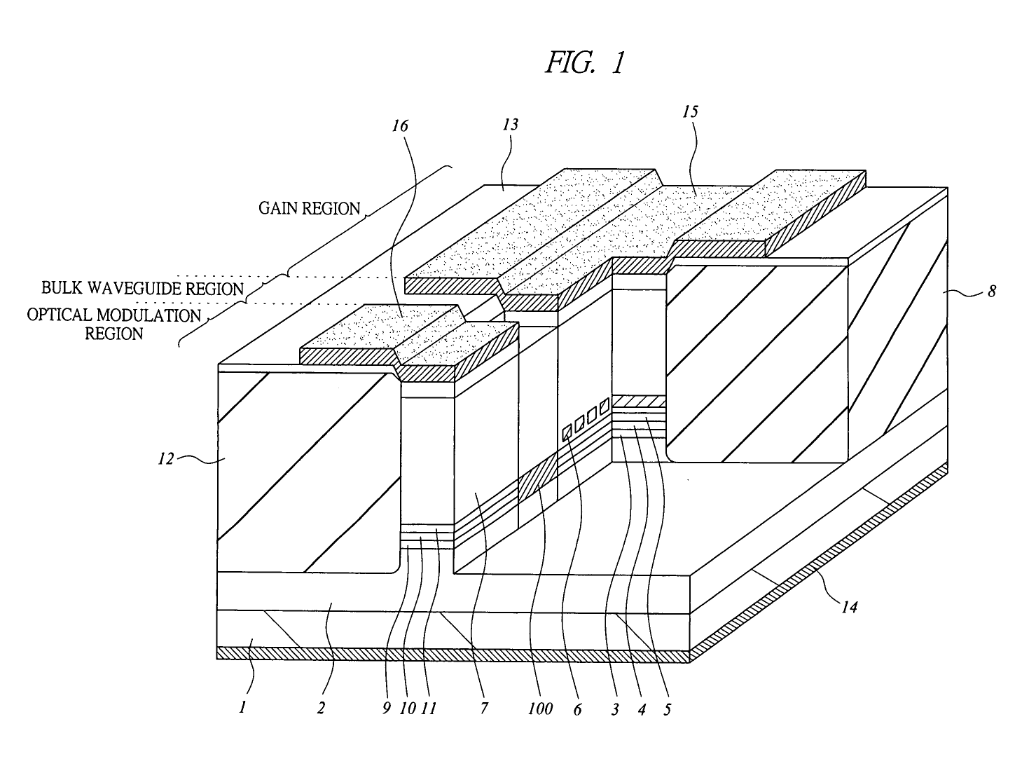

In the first embodiment, the present invention is applied to a semiconductor optical device in which an electro-absorption optical modulator (EA optical modulator) and a distributed feedback (DFB) laser device (DFB laser) are integrated on the same semiconductor substrate, and FIG. 1 is a cutaway perspective view showing the principal part of the integrated semiconductor optical device.

This integrated semiconductor optical device includes three regions such as a gain region, a bulk waveguide region and an optical modulation region arranged along a direction in which the light propagates.

The DFB laser is formed in the gain region. This DFB laser has a hetero structure in which an n-type InP buffer layer 2, an n-type InGaAsP guide layer 3, a QW active layer 4 made up of InGaAsP/InGaAsP, a p-type InGaAsP guide layer 5, a p-type InP spacer layer (not shown), an InGaAsP diffraction grating layer 6 and a p-type InP clad layer 7 are stacked on an n-type InP substrate 1 with a plane orientation of (100). Also, the mesa stripe with the width of about 2 μm and the height of about 3 μm is formed in the layers from the middle of the n-type InP buffer layer 2 to the p-type InP clad layer 7. The regions on both sides of the mesa stripe are buried with a gain region buried layer 8 made of a semi-insulating semiconductor material whose resistivity is adjusted to 10⁹ Ω·cm. This semi-insulating semiconductor material is made of InP doped with Ru.

In the optical modulation region, the electro-absorption optical modulator (EA optical modulator) is formed. This EA optical modulator has a hetero structure in which the n-type InP buffer layer 2, an n-type InGaAlAs guide layer 9, a QW (Quantum-Well) light absorption layer 10 made up of InGaAlAs/InGaAlAs, a p-type InGaAlAs guide layer 11 and the p-type InP clad layer 7 are stacked on the n-type InP substrate 1 with a plane orientation of (100). The mesa stripe with the width of about 2 μm and the height of about 3 μm is formed in the layers from the middle of the n-type InP buffer layer 2 to the p-type InP clad layer 7. The regions on both sides of the mesa stripe are buried with an optical modulation region buried layer 12 made of a semi-insulating semiconductor material whose resistivity is adjusted to 10⁷ Ω·cm. This semi-insulating semiconductor material is made of InP doped with Ru.

In the present embodiment, different from the conventional concept in which the same material is uniformly used as the gain region buried layer 8 and the optical modulation region buried layer 12 to form the buried layers with substantially the same resistivity, the concept in which the gain region buried layer 8 and the optical modulation region buried layer 12 are designed to have different structures is adopted. More specifically, the present embodiment is characterized in that the characteristics of the buried layers represented by the resistivity are made adjustable in the regions of each optical device, while focusing on the point that the buried layer suitable in characteristics of the optical device exists for each of the optical devices.

Furthermore, although the resistivity of the optical modulation region buried layer 12 is set to 10⁷ Ω·cm in the present embodiment, what is important in the present embodiment is that the resistivity of the optical modulation region buried layer 12 is made lower than the resistivity of the gain region buried layer 8, more preferably, made lower by one order of magnitude ( 1/10) or more, thereby achieving the high output of the semiconductor laser and the high-speed modulation of the optical modulator. Conversely, the resistivity of the gain region buried layer 8 is made higher than the resistivity of the optical modulation region buried layer 12. In short, the resistivity is used as the characteristics of the buried layers to be set.

Note that/in the present embodiment, in order to achieve the high output of the semiconductor laser and the high-speed modulation of the optical modulator, the resistivity of the optical modulation region buried layer 12 is made lower than the resistivity of the gain region buried layer 8. However, the relationship in resistivity may be reversed if used for a different optical device. Also, what is important in the present embodiment is that the Fe-doped semi-insulating semiconductor material (crystal) whose resistance is appropriately reduced to an extent that the carriers are not piled up is used for the optical modulation region buried layer 12, and therefore, the efficient carrier path can be formed by itself by the interdiffusion of Zn and Fe. More specifically, since Fe is used as the dopant of the semi-insulating semiconductor crystal, the semi-insulating barrier can be gradually reduced by the thermal diffusion with Zn during the crystal growth, and the leakage of the piled-up carriers to the side-surface portion of the mesa stripe can be appropriately promoted. Further, the Fe diffused from the buried layer to the active region promotes the recombinateion of the generated photocarriers. As described above, in the semiconductor optical device for which the present invention is intended, the optical signals are not taken out unlike the semiconductor light-receiving device in the Patent Document 1, and therefore, the promotion of the non-radiative transition by the impurity doping is effective.

Also, in the buried layer in which Fe is used as dopant, the deterioration in band is more worried compared with the high-resistance buried layer using Ru as dopant. However, since the resistance is also involved in band at the time of the high-speed optical modulation, the high-speed optical modulation characteristics can be more improved in the case of using the Fe-doped buried layer as the optical modulation region buried layer than the case of using the Ru-doped buried layer.

As described above, the material is used for adjusting the characteristics of the buried layers to be set according to an embodiment of the present invention. Note that the adjustment of the resistivity of the buried layers (8, 12) made of the semi-insulating semiconductor materials is desirably performed by the control of the doping material (doped impurity species), doping profile (profile of doped impurity) and the defect density (crystal defect density), but not limited to these.

The bulk waveguide region has a structure in which the n-type InP buffer layer 2, a bulk waveguide 100 and the p-type InP clad layer 7 are stacked on the n-type InP substrate 1 with a plane orientation of (100). The mesa stripe with the width of about 2 μm and the height of about 3 μm is formed in the layers from the middle of the n-type InP buffer layer 2 to the p-type InP clad layer 7. In the sidewall of the mesa stripe of the bulk waveguide region, a waveguide region buried layer made of a semi-insulating, semiconductor material whose resistivity is adjusted to 10⁷ Ω·cm is buried. Note that, in the present embodiment, the same semi-insulating semiconductor material as that of the optical modulation region buried layer 12 is used for the waveguide region buried layer, but the semi-insulating semiconductor material whose resistivity is adjusted to 10⁹ Ω·cm used in the gain region may be used, and other semi-insulating semiconductor materials with different resistivity may also be used. However, the semi-insulating semiconductor material used for the waveguide region buried layer desirably has the resistivity equal to or higher than that of the gain region buried layer 8 from the viewpoint of the isolation of current. In contrast, when the same semi-insulating semiconductor material as that of the gain region buried layer 8 or the optical modulation region buried layer 12 is used for the waveguide region buried layer like in the present embodiment, since the waveguide region buried layer can be formed together with the gain region buried layer 8 or the optical modulation region buried layer 12, this is preferable from the viewpoint of the process simplification. Furthermore, it is also possible to employ the planar layout in which the semi-insulating semiconductor material of the optical modulation region buried layer 12 and the semi-insulating semiconductor material of the gain region buried layer 8 are switched in the middle of the bulk waveguide region.

The reference number 13 in FIG. 1 denotes a passivation film common to the laser device and the optical modulator, 14 denotes an n-type electrode common to the laser device and the optical modulator, 15 denotes a p-type electrode of the laser device, and 16 denotes a p-type electrode of the optical modulator. The passivation film 13 is an insulating film which exposes an upper surface of the mesa stripe and covers the gain region buried layer 8, the waveguide region buried layer and the optical modulation region buried layer 12. The n-type electrode 14 is a metal film formed on a whole rear surface of the n-type InP substrate 1 and is mounted on a sub-mount of the optical module by solder. The p-type electrodes 15 and 16 are connected to electrodes of the optical module by wire bonding and driving signals are supplied to the p-type electrodes 15 and 16.

Next, in order to confirm the effect of the present embodiment, the present embodiment, the comparative example 1 in which the optical modulator is formed to have the ridge waveguide structure and the comparative example 2 in which the optical modulator is formed to have the same mesa stripe structure as that of the first embodiment and this mesa stripe is buried with the semi-insulating semiconductor material whose resistivity is adjusted to 10⁹ Ω·cm which is equal to that of the gain region buried layer 8 are respectively driven and compared under the same condition.

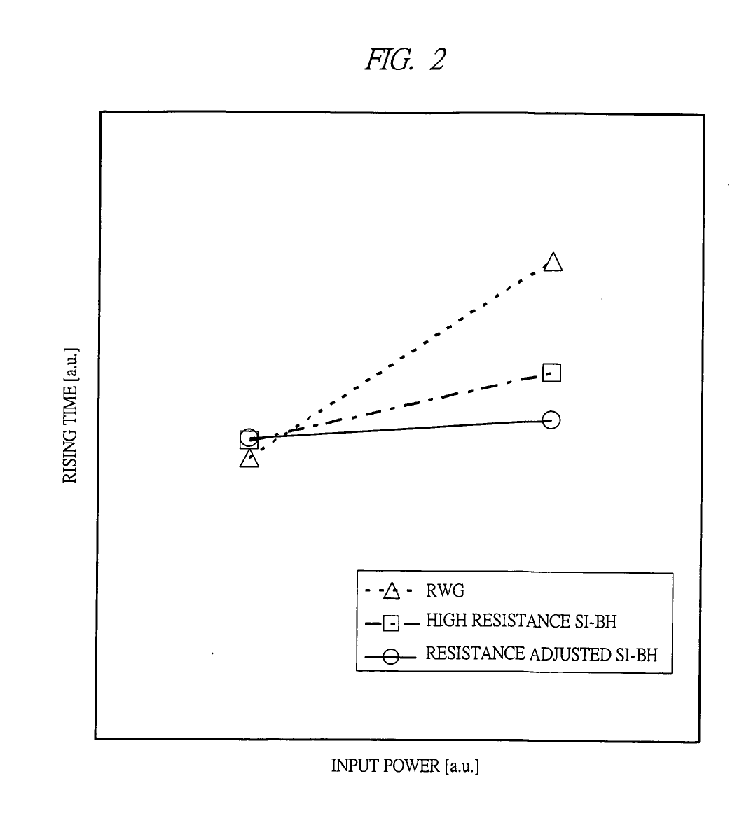

In FIG. 2, the integrated semiconductor optical devices of the present embodiment and the comparative examples 1 and 2 are compared in terms of the rising time of the optical waveform of 10 Gbps at the same light input intensity. It can be confirmed from FIG. 2 that the rising time of the waveform before transmission becomes longer in the comparative examples 1 and 2 (comparative example 1: RWG, comparative example 2: high resistance SI-BH) when the input light is intensified. This is probably because the junction capacitance is increased due to the reduction in the effective electric field by the pile up of the photocarriers and the band of the device is deteriorated. On the other hand, the delay in the rising time like this is scarcely confirmed in the integrated semiconductor optical device of the present embodiment (resistance adjusted SI-BH). It can be understood from the results that the pile up can be suppressed by adjusting the resistivity of the buried layer made of a semi-insulating semiconductor material to about 10⁷ Ω·cm which is lower than 10⁹ Ω·cm of the comparative example 2 by two orders of magnitude. Note that, although the difference in resistivity of about two orders of magnitude is provided in this comparison, it has been known from other experiments that the effect of the present invention can be sufficiently obtained when the resistivity of the optical modulation region buried layer 12 is lower than that of the gain region buried layer 8 by one order of magnitude.

For fabricating the integrated semiconductor optical device in which the high-output-power semiconductor laser device and the high-speed and high-output-power optical modulator are monolithically integrated, it is preferable to adjust the resistivity of the gain region buried layer 8 to 10⁸ Ω·cm or higher and adjust the resistivity of the buried layer of the optical modulator to 10⁴ Ω·cm to 10⁷ Ω·cm. Note that, when the resistivity of the buried layer of the optical modulator is set to lower than 10⁴ Ω·cm, the insulating function does not work practically and it cannot operate as an optical modulator.

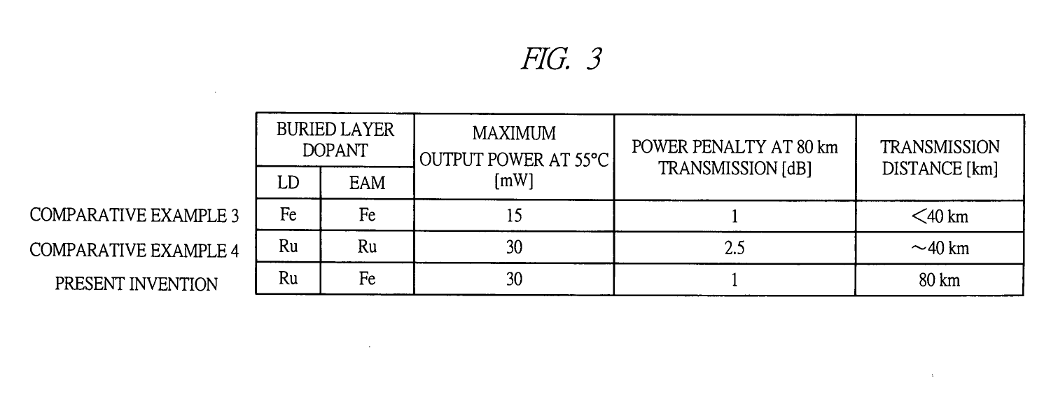

FIG. 3 is a table showing the comparison in the operation at 55° C. of the integrated semiconductor optical devices of the present embodiment and comparative examples 3 and 4. The comparative example 3 is the case in which the high-resistance buried layer of the laser device and the optical modulation region buried layer 12 are respectively made of the Fe-doped semi-insulating semiconductor material (crystal) adjusted to have the same resistivity, and the comparative example 4 is the case in which the gain region buried layer 8 of the laser device and the optical modulation region buried layer 12 are respectively made of the Ru-doped semi-insulating semiconductor material (crystal) adjusted to have the same resistivity.

The comparative example 3 is not suitable for the highly-efficient laser device because the current leakage becomes pronounced, and further, the operation at a high temperature cannot be expected. As a result, the light output becomes insufficient for the 80 km transmission by a general single-mode fiber. Also, the high-output-power and highly-efficient laser device can be fabricated in the comparative example 4, but when the characteristics of the optical modulator are considered, the power penalty is increased due to the influence of the pile up of the carriers, and therefore, it has difficulty in the 80 km transmission.

As described above, it can be understood that the transmission distance is short in the buried structure of the conventional typical integrated optical device, that is, in the approach of the simultaneous formation in which the region for the buried layers of the mesa stripes is not divided based on the resistivity of the buried layer.

On the other hand, since the integrated semiconductor optical device including the high-output-power and highly-efficient optical modulator which can be driven at high speed with reduced current leakage can be fabricated in the present embodiment, the 80 km transmission by a single-mode fiber is possible.

### Second Embodiment

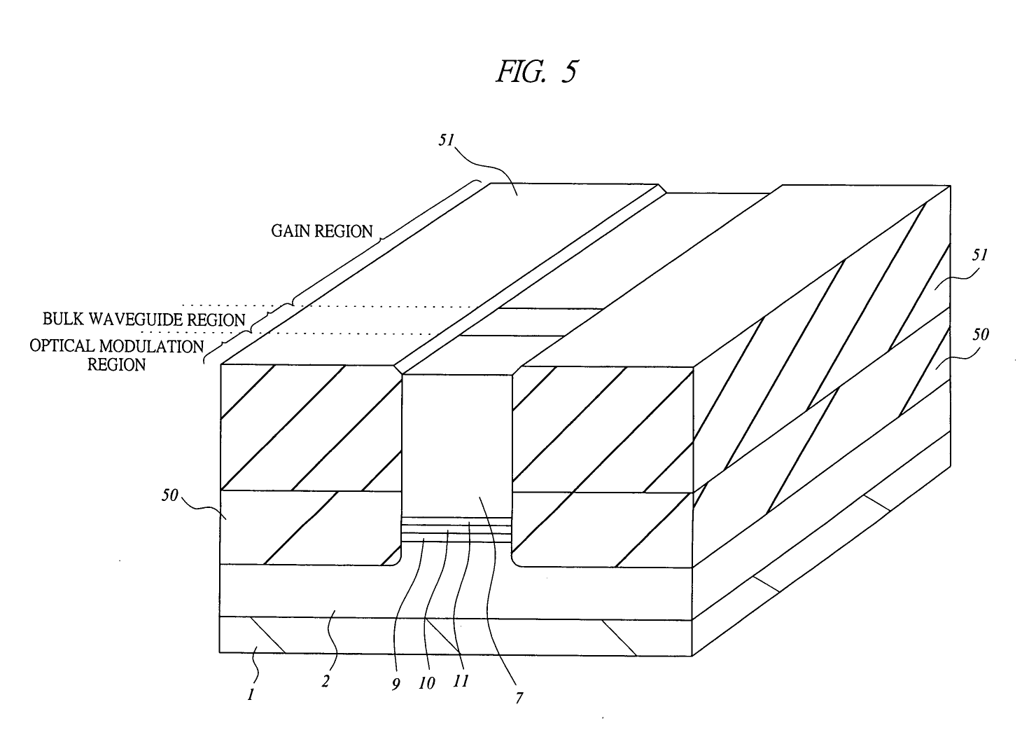

FIG. 5 is a cutaway perspective view showing the principal part of the semiconductor optical device according to the second embodiment. The present embodiment is an integrated semiconductor optical device in which an EA modulator and a DFB laser are integrated on the same semiconductor substrate similar to the first embodiment, but is different from the first embodiment in the structure of the optical modulation region buried layer. More specifically, in the buried layer, the region up to the active region of the mesa stripe is formed of a low-resistance lower-layer buried layer 50 made of the Fe-doped semi-insulating semiconductor crystal whose resistivity is adjusted to be low, and its upper portion is formed of a high-resistance upper-layer buried layer 51 made of the Ru-doped semi-insulating semiconductor crystal. The “high-resistance” and “low-resistance” mentioned here are the expressions based on the relative resistivity values between the lower-layer buried layer 50 and the upper-layer buried layer 51, and the resistivities are set within the same value and range as those of the first embodiment.

The characteristic point of the structure of the present embodiment lies in that the lower-layer buried layer made of the high-resistance Ru-doped semi-insulating semiconductor material is provided as the buried layer in contact with the sidewall of the p-type InP clad layer 7. By this structure, the interdiffusion of the dopants can be suppressed and the parasitic capacitance can be reduced. Also, another characteristic point of the structure of the present embodiment lies in that the upper-layer buried layer 51 made of the low-resistance Fe-doped semi-insulating semiconductor material is provided in the active region (absorption layer) in the mesa stripe of the optical modulation region. By this structure, the pile up can be suppressed.

### Third Embodiment

An example of a manufacturing method of a semiconductor optical device in which an EA modulator and a DFB laser are integrated on the same semiconductor substrate will be described.

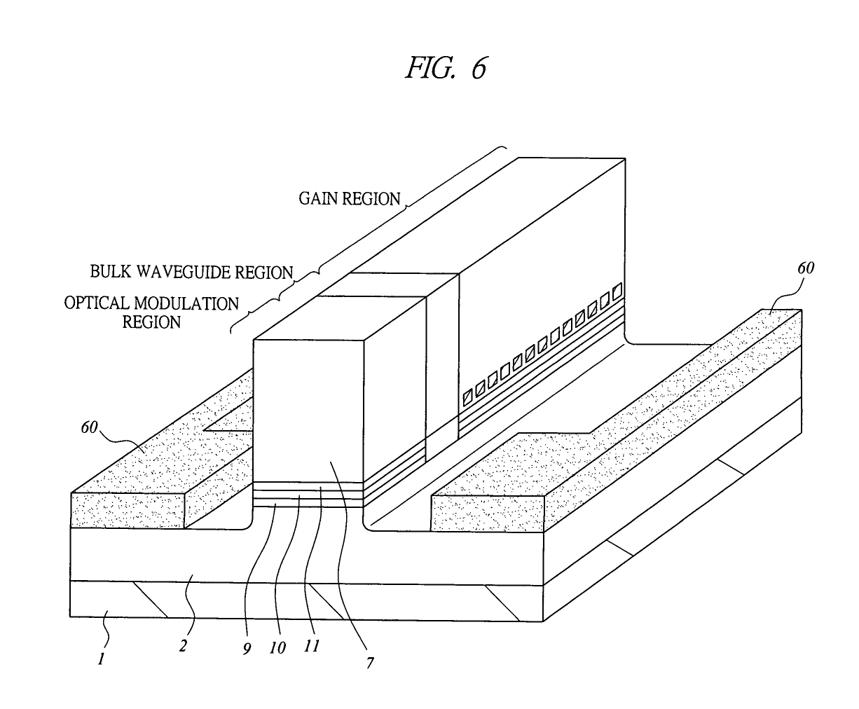

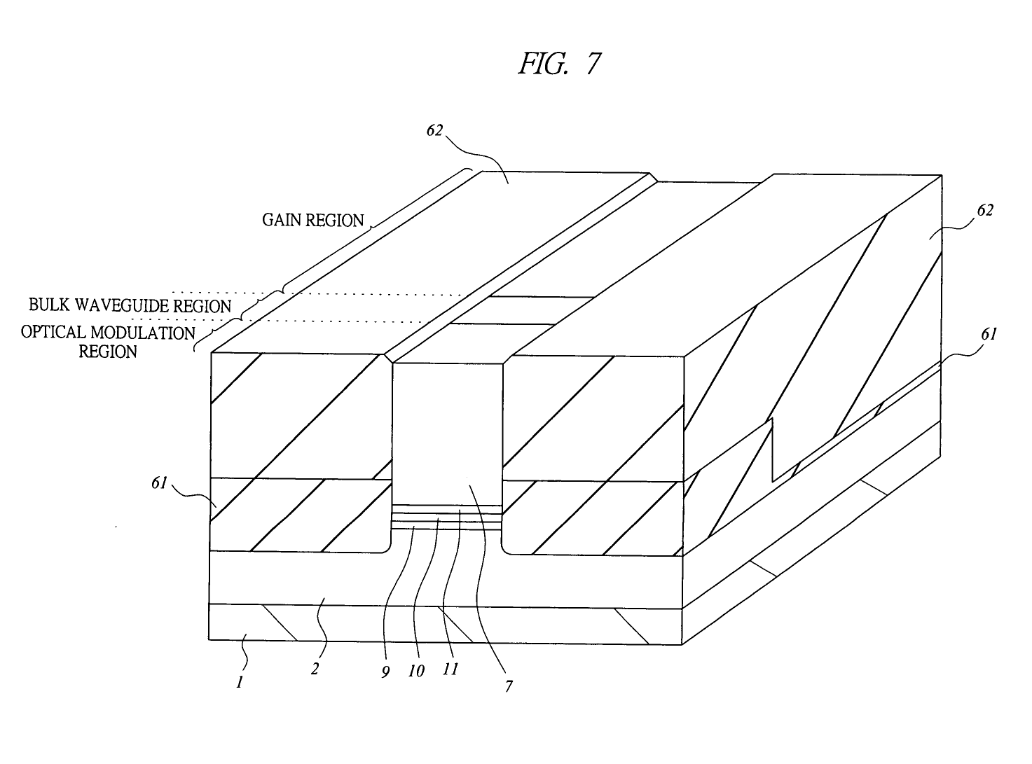

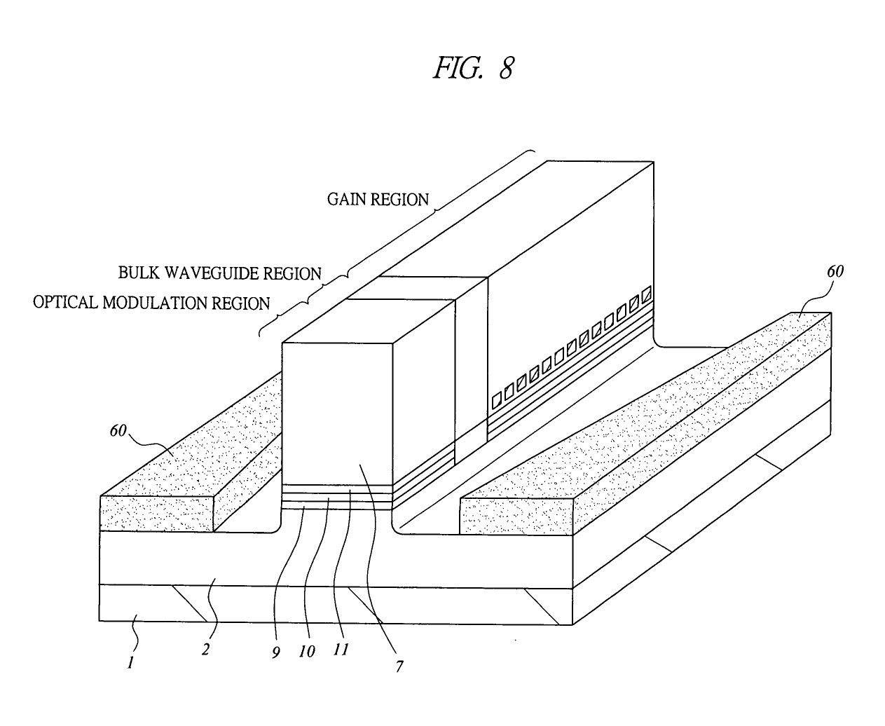

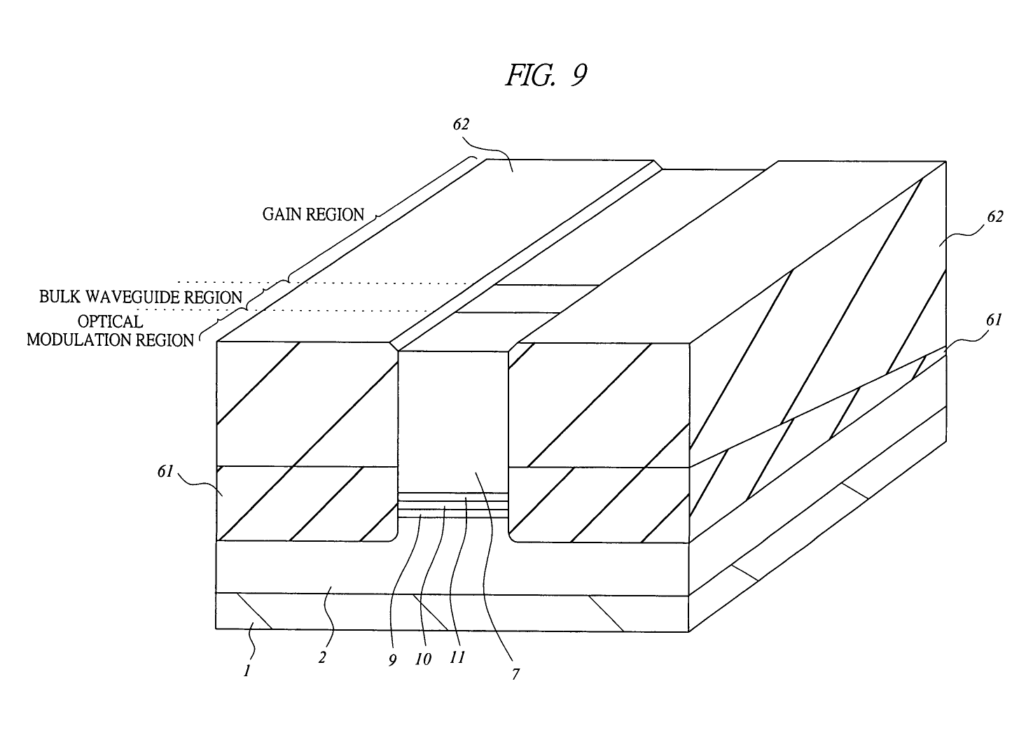

First, as shown in FIG. 6 or FIG. 8, after forming the mesa stripe on the n-type InP substrate 1, a dielectric photomask 60 for selecting the growth region (step-like notch is present for a mesa trench in FIG. 6 and tapered notch is present for a mesa trench in FIG. 8) is formed while changing the opening width for each optical device. Then, by the selective area growth method using the dielectric photomask 60, the growth rates of the optical modulation region buried layer and the gain region buried layer are separately controlled to form a lower-layer buried layer 61 made of a high-resistance semi-insulating semiconductor material and an upper-layer buried layer 62 made of a low-resistance semi-insulating semiconductor material as shown in FIG. 7 or FIG. 9. In the manufacturing method according to the present embodiment, the buried layers with the desired characteristics can be formed by controlling only the switching of the material supply in the growth chamber.

As another manufacturing method, after simultaneously performing the burying growth of the sidewalls of the mesa stripe of the optical modulator and the mesa stripe of the laser device, the formation of the mesa stripe and the burying growth are repeated again by the selective etching using a dielectric mask, thereby forming the lower-layer buried layer 61 and the upper-layer buried layer 62.

### Fourth Embodiment

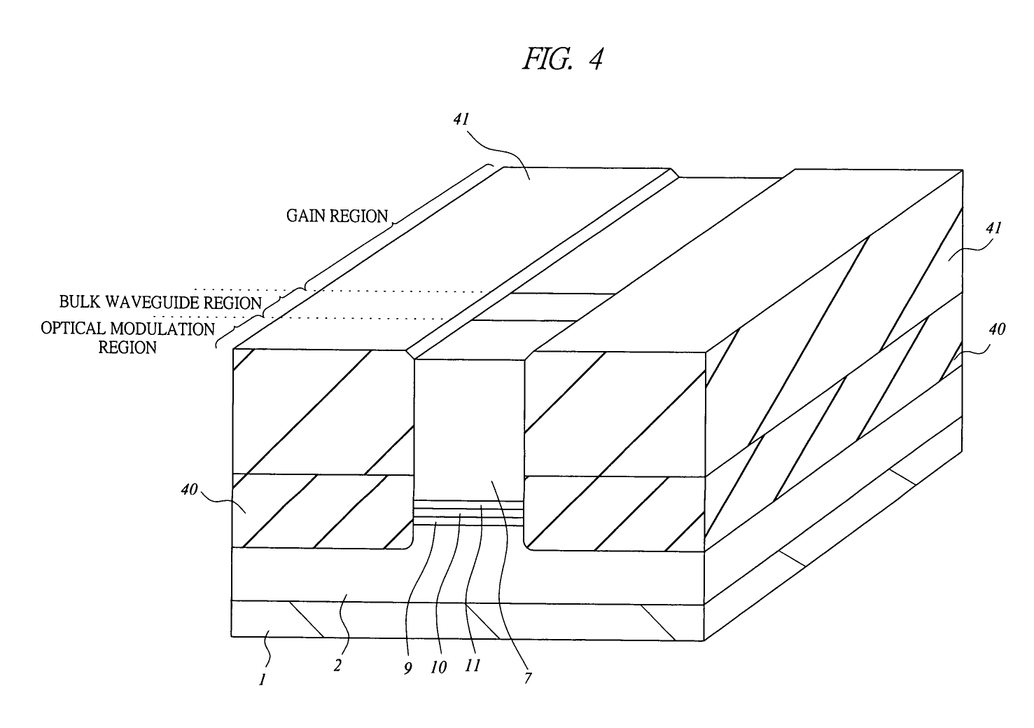

FIG. 4 is a cutaway perspective view showing the principal part of the integrated semiconductor optical device according to the fourth embodiment.

The present embodiment is a semiconductor optical device in which an EA optical modulator and a DFB laser are integrated on the same semiconductor substrate similar to the second embodiment, but is different from the first embodiment in the stacking order of the buried layers. More specifically, in the buried layer, the region up to the active region of the mesa stripe is formed of a high-resistance lower-layer buried layer 40 made of the Ru-doped semi-insulating semiconductor crystal, and an upper portion of the lower-layer buried layer 40 is formed of an upper-layer buried layer 41 made of a semi-insulating semiconductor crystal adjusted to have a resistance lower than that of the lower-layer buried layer 40.

Although the effect of the suppression of the pile up cannot be sufficiently achieved in the present embodiment, the present invention is described here because it is of a similar type to the second embodiment. According to the present embodiment, since the buried layer in contact with the p-type InP clad layer 7 is the upper-layer buried layer 41 adjusted to have a low resistance; the device resistance can be lowered. Also, since the sidewall of the active region is buried with a high-resistance lower-layer buried layer 40 doped with Ru which is not likely to diffuse, the penetration of the defective atoms into the active region can be suppressed. Furthermore, since the current is effectively confined, the current use efficiency is improved. Also, in general, the higher-quality semiconductor crystal can be formed in the buried layer whose resistivity is adjusted compared with the high-resistance buried layer. Therefore, since the surface flatness and morphology of the upper-layer buried layer 41 are improved, the disconnection caused by the step of the electrode and the passivation film formed on the upper-layer buried layer 41 can be prevented.

### Fifth Embodiment

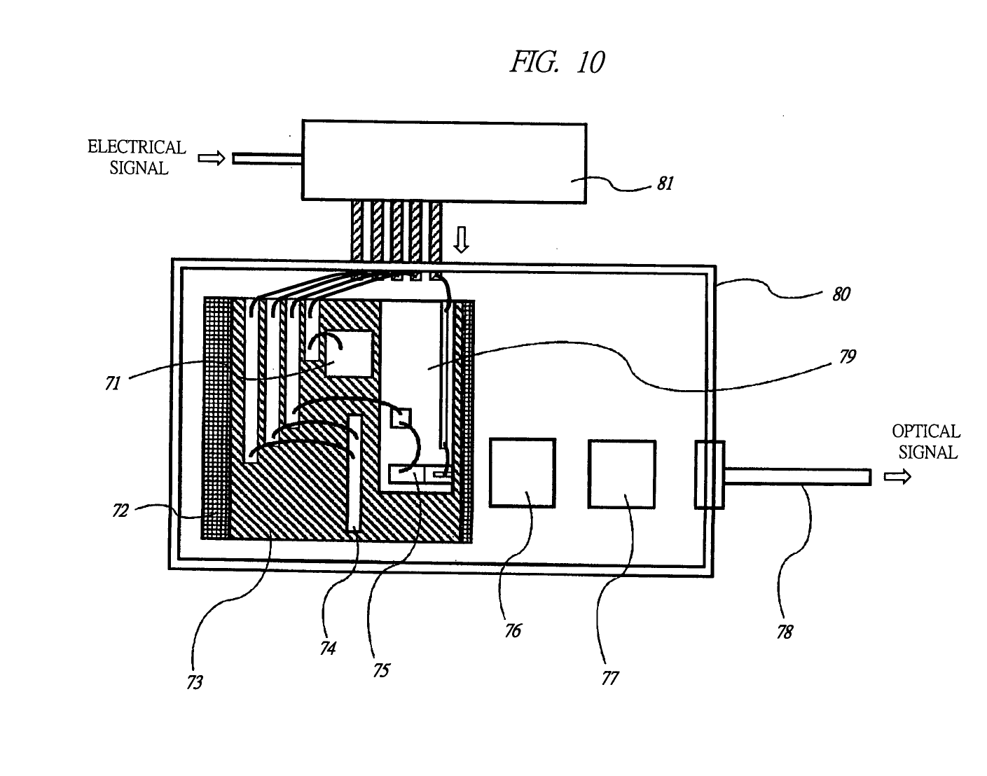

FIG. 10 shows a transceiver formed by using the integrated semiconductor optical device according to one of the first to fourth embodiments.

The integrated semiconductor optical device 75 according to one of the first to fourth embodiments is mounted on a sub-mount 79 made of, for example, AlN or SiC, and the sub-mount is further fixed to a carrier 73 by solder. Furthermore, the carrier is mounted on a Peltier cooler 72 and is stored in an air-tight sealed case 80. The input electrical signal waveform is adjusted in a driver 81 disposed outside the air-tight case. Leads shielded by insulator are penetrated through the sidewall of the air-tight case, and the electrical signal whose waveform has been adjusted by the driver passes through the leads. The electrical signal is coupled to the microstrip line on the sub-mount to drive the wire-bonded optical modulator.

A reference number 71 in FIG. 10 denotes a thermistor, which monitors the temperature of the carrier and feeds it back to the electrical output of the driver. Also, 74 denotes a photodiode, which monitors the intensity of the light irradiated from an opposite side of the modulator of the integrated semiconductor optical device and feeds it back to the electrical output of the driver. Further, 77 denotes an aspheric lens for fiber coupling, 76 denotes an isolator and 78 denotes a single-mode fiber.

Note that, although the driver is installed outside the air-tight case, the driver may be installed inside the case, and although the driver and the device of the module are connected through wires and leads, these may be monolithically integrated in the same chip. The Peltier cooler does not have to be installed depending on the intended use of the module.

By applying the integrated semiconductor optical device in which both the increase in light output of the semiconductor laser and the optical amplifier and the high-speed optical modulation of the optical modulator are achieved to a transceiver as described in the present embodiment, the long-distance and large-capacity transmission can be realized.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the above-described embodiments, the integrated semiconductor optical device in which the EA modulator and the DFB laser are integrated on the same semiconductor substrate has been exemplified, but this is the detailed disclosure of the preferred embodiment and the present invention is not limited only to the embodiment. As the optical modulator to be integrated, an MZ optical modulator and an optical phase modulator are also available.

Further, the semiconductor material, the dimensions of the mesa stripe, the film thickness and the semiconductor substrate are the detailed disclosure of the preferred embodiment for making the invention of the present application easily understood, and the present invention is not limited only to the embodiment.

Furthermore, the first embodiment includes the concept of forming the buried layers for each region of the optical device while adjusting the resistivity thereof, and therefore, it is needless to say that the present invention can be used also for any integrated semiconductor optical device of an active device and a passive device other than the combination of an optical modulator and a gain device (laser or amplifier) if the device adopts the buried structure.

1. An integrated semiconductor optical device in which an optical modulator and a semiconductor laser device or an optical amplifier are monolithically integrated on the same semiconductor substrate,
wherein the optical modulator and the semiconductor laser device or the optical amplifier which make up the integrated semiconductor optical device each include a mesa stripe which forms a hetero structure and a buried layer obtained by burying the mesa stripe with a semi-insulating semiconductor material,
an active layer of the mesa stripe which forms the hetero structure of the semiconductor laser device or the optical amplifier is buried with a first buried layer,
an active layer of the mesa stripe which forms the hetero structure of the optical modulator is buried with a second buried layer, and
the first buried layer and the second buried layer have different configurations.

2. The integrated semiconductor optical device according to claim 1,
wherein the different configurations are different resistivities.

3. The integrated semiconductor optical device according to claim 2,
wherein the resistivity of the second buried layer is higher than the resistivity of the first buried layer.

4. The integrated semiconductor optical device according to claim 3,
wherein there is ten times or more difference between the resistivity of the first buried layer and the resistivity of the second buried layer.

5. The integrated semiconductor optical device according to claim 4,
wherein the resistivity of the second buried layer is 10⁴ to 10⁷ Ω·cm.

6. The integrated semiconductor optical device according to claim 4,
wherein the resistivity of the first buried layer is 10⁸ Ω·cm or higher.

7. The integrated semiconductor optical device according to claim 3,
wherein the semiconductor laser device is a distributed feedback laser device.

8. The integrated semiconductor optical device according to claim 7,
wherein the second buried layer is made of a semi-insulating semiconductor material doped with Fe, and
the first buried layer is made of a semi-insulating semiconductor material doped with Ru.

9. The integrated semiconductor optical device according to claim 3,
wherein the optical modulator is an electro-absorption optical modulator.

10. The integrated semiconductor optical device according to claim 3,
wherein the optical modulator is a Mach Zehnder optical modulator or an optical phase modulator.

11. The integrated semiconductor optical device according to claim 2,
wherein the resistivity of the first buried layer is higher than the resistivity of the second buried layer.

12. An optical module in which the integrated semiconductor optical device in which an optical modulator and a semiconductor laser device or an optical amplifier are monolithically integrated on the same semiconductor substrate,
wherein the optical modulator and the semiconductor laser device or the optical amplifier which make up the integrated semiconductor optical device each include a mesa stripe which forms a hetero structure and a buried layer obtained by burying the mesa stripe with a semi-insulating semiconductor material,
an active layer of the mesa stripe which forms the hetero structure of the semiconductor laser device or the optical amplifier is buried with a first buried layer,
an active layer of the mesa stripe which forms the hetero structure of the optical modulator is buried with a second buried layer, and
the first buried layer and the second buried layer have different configurations is mounted.

13. A manufacturing method of an integrated semiconductor optical device in which an optical modulator and a semiconductor laser device or an optical amplifier are monolithically integrated on the same semiconductor substrate, and the optical modulator and the semiconductor laser device or the optical amplifier each include a mesa stripe having a hetero structure and a buried layer obtained by burying the mesa stripe with a semi-insulating semiconductor material,
the manufacturing method comprising:
a first step of burying an active layer of the mesa stripe of the semiconductor laser device or the optical amplifier with a first semi-insulating semiconductor material doped with an impurity, thereby forming a first buried layer; and
a second step of burying an active layer of the optical modulator with a second semi-insulating semiconductor material doped with an impurity, thereby forming a second buried layer,
wherein a resistance of the first buried layer and a resistance of the second buried layer are made different by controlling species of the doped impurities, profiles of the doped impurities or crystal defect densities of the semi-insulating semiconductor materials.
